(19) United States
(12) Patent Application Publication
(10) Pub. No.: US 2016/0155495 A1
(43) Pub. Date: Jun. 2, 2016

(54) MEMORY SYSTEM AND METHOD FOR PROCESSING DATA IN MEMORY

(71) Applicant: WILUS INSTITUTE OF STANDARDS AND TECHNOLOGY INC., Seoul (KR)

(72) Inventor: Hyunoh OH, Gwacheon-si, Gyeonggido (KR)

(73) Assignee: WILUS INSTITUTE OF STANDARDS AND TECHNOLOGY INC., Seoul (KR)

(21) Appl. No.: 14/903,600

(22) PCT Filed: Jul. 8, 2014
(86) PCT No.: PCT/KR2014/006098

§ 371 Date: Jan. 8, 2016

Related U.S. Application Data
(60) Provisional application No. 61/843,898, filed on Jul. 8, 2013.

(51) Int. Cl. G11C 11/56; G11C 16/10

(52) U.S. Cl. CPC G11C 11/5628; G11C 16/10

(57) ABSTRACT

The present invention relates to a memory system and a method for processing data in a memory, and more particularly, to a memory system and a method for processing data in a memory for efficiently processing data.

To this end, provides are a method for processing data in a memory, including: obtaining programming count information of a page on which data is to be programmed; determining a driving voltage value set including a lowest level value and a highest level value to be programmed on each memory cell in the page based on the obtained programming count information; and programming the data on each memory cell in the page by using a plurality of voltages between the lowest level value and the highest level value of the determined driving voltage value set, in which the lowest level value and the highest level value are shifted according to an increase in the programming count information and a memory system using the same.

### TECHNICAL FIELD

The present invention relates to a memory system and a method for processing data in a memory, and more particularly, to a memory system and a method for processing data in a memory for efficiently processing data.

### BACKGROUND ART

A memory device is the most requisite microelectronic element in a digital logic design. The memory device is largely divided into a volatile memory device and a non-volatile memory device. Although a power of the non-volatile memory device is cut off, the non-volatile memory device can store data. The data stored in the non-volatile memory can be permanent or reprogrammed according to a memory manufacturing technique. The non-volatile memory device can be used in applications of various industrial fields.

As a representative example of the non-volatile memory, a flash memory is provided. The flash memory can be used in numerous media storing data, such as a smart phone, a digital camera, a solid-state drive (SSD), and a black box. In particular, since the SSD using a NAND flash memory has small power consumption, can be miniaturized, and is resistant to impact as compared with a hard disk drive (HDD), the SSD is widely used as storage media in a laptop, a desktop, and a server. Furthermore, in recent years, with the development of the smart phone and the SSD, availability of the NAND flash memory has gradually increased.

Basically, a cell of the flash memory can write and erase data by filling and emptying electrons in and from a floating gate.

In more detail, when voltage enough to cause a tunnel effect is applied to a control gate in a state of an empty cell, some of the electrons which move from a source to a drain pass through an oxide film which is an insulator due to an influence of an electric field generated according to the applied voltage to fill the electrons of the floating gate. Next, when the applied voltage is cut off, the electrons filled in the floating gate covered with the insulator are confined in the floating gate. Therefore, the electrons can remain filled in the floating gate even though power is not supplied. A write operation of the flash memory cell can be implemented by the aforementioned operations.

When positive voltage which may cause a tunnel release is applied to a P layer while the electrons are filled in the floating gate, the electrons confined in the floating gate can be discharged to the outside of the floating gate through an insulating layer. As a result, the cell may return to an empty state again. An erase operation of the flash memory cell can be implemented by the aforementioned operations.

However, the NAND flash memory has a disadvantage in that overwrite in-place of data is not permitted unlike a DRAM or the HDD. That is, for overwriting, a part previously written in the memory cell is erased and thereafter, overwriting needs to be performed. In other words, before data is written in the flash memory, the data needs to return to an initial state or an erased state. This is referred to as an erase-before-write operation. Therefore, a problem occurs, in which an entire block is first erased and thereafter, all pages in the corresponding block need to be rewritten in spite of changing data of 1 byte due to a characteristic of a cell in which overwriting is impossible (herein, the minimum wise of writing and reading of the NAND flash memory is the page and the minimum wise of erase is the block).

Further, since a state change of the memory cell described above causes abrasion of the memory cell, only a predetermined count of overwriting can be generally permitted in the cell of the flash memory. That is, when the predetermined overwriting count is exceeded, additional overwriting is not permitted any more and only reading is just possible.

Due to an attribute of the data that is stored in the flash memory, updated periods may vary according to a type of data. For example, most of the data files with a small capacity are frequently written and erased (that is, updated), while most of data files with a large capacity may be accessed only for the reading operations. Further, meta data may be one of hot data which are more frequently updated than general data. Accordingly, there is a need for a method of increasing the lifespan of the flash memory by considering the viewpoints.

### DISCLOSURE

### Technical Problem

The present invention has been made in an effort to efficiently use a memory system.

### Technical Solution

An exemplary embodiment of the present invention provides a method for processing data in a memory, including: obtaining programming count information of a page on which data is to be programmed; determining a driving voltage value set including a lowest level value and a highest level value to be programmed on each memory cell in the page based on the obtained programming count information; and programming the data on each memory cell in the page by using a plurality of voltages between the lowest level value and the highest level value of the determined driving voltage value set, in which the lowest level value and the highest level value are shifted according to an increase in the programming count information.

In the determining, the driving voltage set may be determined based on a value of ‘the programming count information (mod ‘the total number of driving voltage level values of the memory cell−1’)’.

The programming count information may increase by 1 according to a programming request of data, and in the determining, a lowest level value and a highest level value of the memory cell to which a first level value and a second level value are allocated, respectively may be changed to the second level value and a third level value.

According to another exemplary embodiment of the present invention, the page may include a pilot cell at a predetermined position, which is set to have a threshold voltage between the lowest level value and the highest level value and a data cell in which the data is programmed and the threshold voltage value programmed to the pilot cell is shifted according to the increase in the programming count information, and the method may further includes, in response to a read request of the data written in the page, reading a voltage value written in the pilot cell; setting a read voltage value for reading the data cell by referring to the read voltage value of the pilot cell; and reading the data of the data cell based on the set read voltage value.

According to yet another exemplary embodiment of the present invention, the memory cell may be a multi level cell (MLC) and the method may include determining the size of data of which programming is requested; programming the data to each memory cell with 1-bit information using the lowest level value and the highest level value when the determined size of the data is smaller than a half of the size of the page; shifting the lowest level value and the highest level value in response to the overwrite request of the data; and reprogramming the data to each memory cell of the page by using the shifted lowest level value and highest level value.

Another exemplary embodiment of the present invention provides a memory system including: a memory having a plurality of physical blocks, each of the plurality of physical blocks including a plurality of pages; and a memory controller configured to control the memory, in which the memory controller includes a programming module for writing/erasing data in/from the memory, a reading module for reading the data written in the memory, and a control module controlling the programming module and the reading module, the control module obtains programming count information of a page in which data is to be programmed and determines a driving voltage value set including a lowest level value and a highest level value to be programmed in each memory cell in the page based on the obtained programming count information, the programming module programs the data in each memory cell in the page by using a plurality of voltages between the lowest level value and the highest level value of the determined driving voltage value set, and the lowest level value and the highest level value are shifted according to an increase in the programming count information.

Still yet another exemplary embodiment of the present invention provides a data processing method in a memory, including: programming data by applying a voltage having a predetermined nominal value to a pilot cell at a predetermined position in the memory; reading a written voltage value of the pilot cell; adjusting a nominal value corresponding to the data based on the read voltage value of the pilot cell; and programming the data to a data cell of the memory by using the adjusted nominal value.

In this case, in the reading, the voltage value of the pilot cell may be read with higher resolution than a voltage step among the respective data for the programming.

The adjusting may include calculating a difference value between the read voltage value of the pilot cell and the predetermined nominal value, and obtaining the adjusted nominal value by adding the calculated difference value to the predetermined nominal value.

The adjusting may include calculating a ratio between the read voltage value of the pilot cell and the predetermined nominal value, and obtaining the adjusted nominal value by scaling the predetermined nominal value based on the calculated ratio.

The pilot cell may be positioned in the same block or page as the data cell.

The data processing method may further include: obtaining information on the number of erase times of a block or information on the number of write times of a page at which the pilot cell is positioned; and shifting the position of the pilot cell based on the information on the number of erase times or the information on the number of write times.

The pilot cell may include a plurality of cells corresponding to a plurality of nominal values used for programming the memory, respectively.

Still another exemplary embodiment of the present invention provides a memory system including: a memory having a plurality of physical blocks, each of the plurality of physical blocks including a plurality of pages; and a memory controller configured to control the memory, in which the memory controller includes a programming module for writing/erasing data in/from the memory, a reading module for reading the data written in the memory, and a control module controlling the programming module and the reading module, the programming module programs data by applying voltage having a predetermined nominal value to a pilot cell at a predetermined position in the memory, the reading module reads a written voltage value of the pilot cell, and the control module adjusts a nominal value corresponding to the data based on the read voltage value of the pilot cell and programs the data to a data cell of the memory by using the adjusted nominal value.

Still yet another exemplary embodiment of the present invention provides data processing method in a memory, including: programming data to a pilot cell and a data cell in the memory by using voltage of a predetermined nominal value, the pilot cell indicating a cell at a predetermined position corresponding to each of at least one nominal value used for programming the memory; reading a written voltage value of the pilot cell; setting a threshold voltage value for reading the data cell by referring to the read voltage value of the pilot cell; and reading the data of the data cell of the memory based on the set threshold voltage value.

In this case, in the reading, the voltage value of the pilot cell may be read with higher resolution than a voltage step among the respective data for the programming.

The pilot cell may be positioned in the same block or page as the data cell.

The data processing method may further include: obtaining information on the number of erase times of a block or information on the number of write times of a page at which the pilot cell is positioned; and shifting the pilot cell based on the information on the number of erase times or the information on the number of write times.

The pilot cell may include a plurality of cells corresponding to a plurality of nominal values used for programming the memory, respectively.

The setting of the threshold voltage value may include obtaining read voltage values of a plurality of pilot cells programmed by using the same nominal value in the memory, and the threshold voltage value may be set based on an average of the obtained read voltage values of the plurality of pilot cells.

Still yet another exemplary embodiment of the present invention provides a memory system including: a memory having a plurality of physical blocks, each of the plurality of physical blocks including a plurality of pages; and a memory controller configured to control the memory, in which the memory controller includes a programming module for writing/erasing data in/from the memory, a reading module for reading the data written in the memory, and a control module controlling the programming module and the reading module, the programming module programs data to a pilot cell and a data cell in the memory by using voltage having a predetermined nominal value, the pilot cell is a cell at a predetermined position corresponding to each of at least one nominal value used for programming the memory, the reading module reads a written voltage value of the pilot cell, the control module sets a threshold voltage value for reading the data cell by referring to the read voltage value of the pilot cell, and the reading module reads the data of the memory cell of the memory based on the set threshold voltage value.

### Advantageous Effects

According to the exemplary embodiments of the present invention, the memory system can be efficiently used.

### DESCRIPTION OF DRAWINGS

FIG. 1 exemplarily illustrates characteristics of an SLC and an MLC.

FIG. 2 is a diagram schematically illustrating a memory system 200 according to an aspect of the present invention.

FIG. 3 is a diagram schematically illustrating a memory system 300 according to one aspect of the present invention.

FIG. 4 exemplarily illustrates an overwrite scheme in one cell of a memory device according to an aspect of the present invention.

FIG. 5 exemplarily illustrates an overwrite scheme in one cell of a memory device according to another aspect of the present invention.

FIG. 6 is a flowchart of a method for processing data in a memory according to an aspect of the present invention.

FIG. 7 exemplarily illustrates a data block including pilot cells according to an aspect of the present invention.

FIG. 8 exemplarily illustrates a change in arrangement of pilot cells according to a programming count and a page according to an aspect of the present invention.

FIG. 9 exemplarily illustrates a reading method using pilot cells in a page according to an aspect of the present invention.

FIG. 10 exemplarily illustrates a change in threshold voltage after data programming.

FIG. 11 exemplarily illustrates a voltage reading mechanism using pilot cells according to an aspect of the present invention.

FIG. 12 exemplarily illustrates a voltage reading method of a data cell using a switch according to an aspect of the present invention.

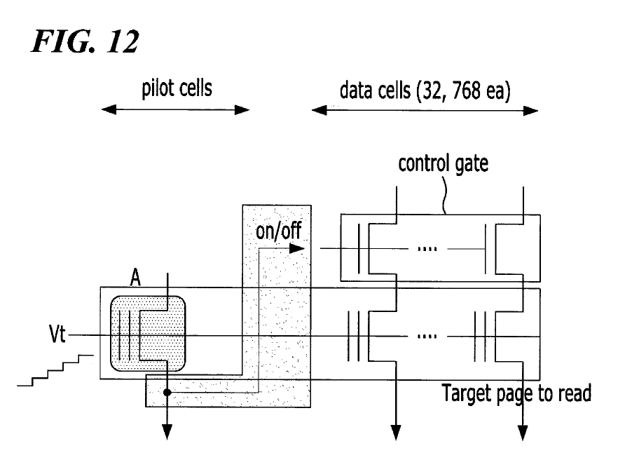

FIG. 13 exemplarily illustrates a data cell reading method using a switch according to an aspect of the present invention.

FIG. 14 exemplarily illustrates a change in threshold voltage after data programming.

FIG. 15 is a flowchart of a method for processing data in a memory according to an aspect of the present invention.

FIG. 16 is a flowchart of a method for processing data in a memory according to another aspect of the present invention.

### BEST MODE

Various aspects are now described with reference to the drawings and like reference numerals are generally used to designate like elements. In the following exemplary embodiments, for description, multiple specific detailed matters are presented to provide general understanding of one or more aspects. However, it will be apparent that the aspects can be implemented without the detailed matters.

Various aspects of the disclosed contents will be described below. The descriptions in the specification may be implemented in broad forms. Further, it is apparent that a predetermined specific structure, functionality, or both of them disclosed herein are just representative. Based on the description in the specification, those skilled in the art should recognize that the aspect disclosed herein can be implemented independently from any other aspects and two or more aspects among the aspects can be combined by various methods. For example, an apparatus can be implemented or a method can be executed by using a predetermined number of aspects presented herein. Further, the apparatus can be implemented or the method can be executed by using other structures, functionalities, or structures and functionalities other than or in addition to one or more aspects among the aspects presented herein. Moreover, an aspect of the present invention may include at least one element of claims.

The specification exemplarily discloses a flash memory, but other memory devices (for example, volatile memories) other than the flash memory (that is, non-volatile memory) may also be included in the scope of the present invention. Further, “unit of information” as a term used in the specification may represent a unit by which data, and the like may be stored or expressed in a data storage system or a communication system. For example, as the unit of information, bit, byte, trit, ban, decit, dit, decimal digit, nat, nit, nepit, and the like may be provided. In the specification described below, as one example of the unit of information, the bit will be disclosed, but units of information other than the bit may also be included in the scope of the specification.

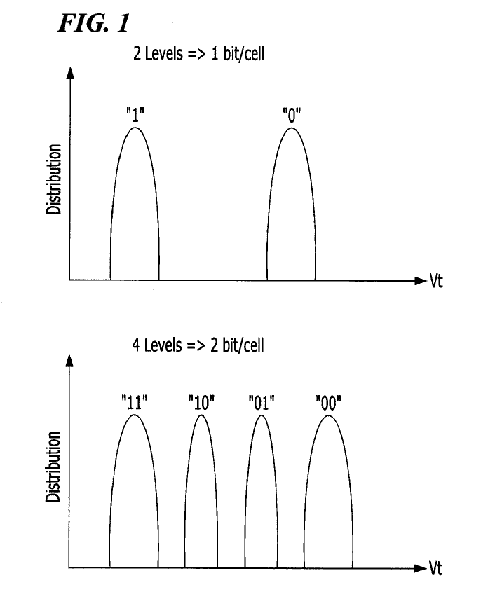

FIG. 1 exemplarily illustrates characteristics of an SLC and an MLC.

Cells used in a NAND flash memory include a single level cell (SLC), a multi level cell (MLC), and a triple level cell (TLC). The cells may be classified into the SLC, the MLC, and the TLC according to a scheme that stores data in the cell that is a minimum unit for storing the data in the flash memory. In other words, cells constituting the flash memory are the same as each other, but the cells may be divided into the SLC, the MLC, and the TLC according to an operating scheme of the cells. In the case of the SLC, information (that is, two states) of 1 bit may be stored in one cell, in the case of the MLC, information (that is, four states) of 2 bits may be stored in one cell, and in the case of the TLC, information (that is, eight states) of 3 bits may be stored in one cell.

Therefore, the MLC and the TLC capable of storing more bits in one cell may have a larger capacity than the SLC, but in terms of the performance and lifetime of the flash memory, the SLC>the MLC>the TLC. The MLC and the TLC variously distribute the quantity (that is, a magnitude or state of voltage) of electrons filled in a floating gate to permit multi bits (that is, various states) to be written in one cell, and as a result, the MLC and the TLC may be lower than the SLC in terms of writing and reading speeds and have a high occurrence rate of an error. In other words, since the MLC and the TCL need to use ECC at a higher level than the SLC, a load to a system may be aggravated. Moreover, since a difference in voltage decreases for each state as the number of bits written in one cell increases, when a resistance value of an oxide film increases due to electrons accumulated in the oxide film in the memory cell, it is impossible to distinguish the states by making the voltage different. Therefore, the MLC and the TLC may have a shorter lifetime than the SLC.

Nevertheless, since the MLC has a larger storing capacity per cell than the SLC, the MLC has an advantage in terms of production cost. Further, the MLC has an advantage in that the MLC has a longer lifetime and better performance than the TLC. The MLC has been used in a lot of applications in recent years.

As illustrated in FIG. 1, in the case of the SLC, two states (that is, 1 bit of 1 and 0) may be written in one cell through two types of voltage magnitudes. In the case of the MLC, four states (that is, 2 bits of 11, 10, 01, and 00) may be written in one cell through four types of voltage magnitudes. For example, in the case of the SLC, a writing operation may be performed by a scheme that implements switching from an erase state ‘1’ to the other state (for example, a write state) ‘0’ by shifting a value of threshold voltage Vt. Further, the state of charged electrons may return to 1 from 0 by an erasing operation again.

In the specification, as a type of cell of the non-volatile memory, the MLC is described as an example, but a memory cell having additional levels other than the TLC may also be included in the scope of the present invention.

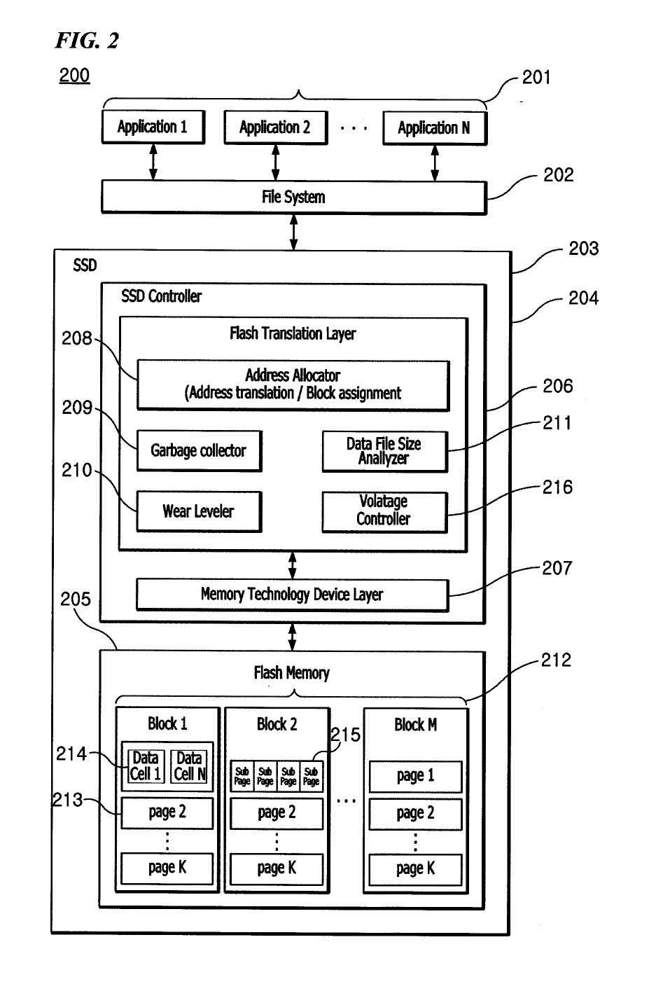

FIG. 2 is a diagram schematically illustrating a memory system 200 according to an aspect of the present invention.

In FIG. 2, the memory system 200 may be largely constituted by an application 201 (alternatively, host), a file system 202, and an SSD 203. Components in FIG. 2 are just examples and some of the components in FIG. 2 may be omitted or components other than the components in FIG. 2 may be included in the memory system 200. Additionally, the SSD 203 in FIG. 2 may be substituted with a memory device and a memory controller capable of performing similar functions.

In one aspect of the present invention, applications 1 to N 201 may include a predetermined device or program requiring data storage to the flash memory device such as the SSD.

In one aspect of the present invention, the file system 202 may be designated as the host or an application area together with the application 201. The file system 202 may access predetermined data of the SSD through a logical sector address. In this case, a flash translation layer 206 of an SSD controller 204 translates the logical sector address into a physical address to map the logical sector address and the physical address. Additionally, the file system 202 may represent a virtual sector implemented by the flash translation layer 206. Further, the file system 202 in the specification may be used to be exchanged with the application 201.

Due to a physical characteristic of the flash memory 205, separate management of a read/write/erase operation is required to use the flash memory 205 like a hard disk. The flash translation layer 206 may represent system software developed for such a purpose. The flash translation layer 206 may include a mapping algorithm translating the logical address into the physical address, an algorithm for determining a data file size, an algorithm for partitioning the pages of the flash memory 205 into a plurality of subpages an algorithm for performing wear leveling, an algorithm for controlling voltage to be applied to the flash memory 205, and the like.

In one aspect of the present invention, the flash translation layer 206 of the SSD controller 204 may include an address allocator 208 for mapping the logical address onto the physical address, a wear leveler 210 for performing the wear leveling, a garbage collector 209, a data file size analyzer 211 for analyzing and comparing the size of a data file, and a voltage controller 216 for controlling voltage to be applied to the flash memory 205. Additionally, the components of the flash translation layer 206 are just examples and additional components may be included in the flash translation layer 206 or some of the components may be omitted.

The wear leveler 210 may perform the wear leveling in a block-wise, a page-wise, and/or a bit-wise, in order to increase the lifetime of the flash memory 205.

The garbage collector 209 performs an operation of marking unnecessary data (invalid data or obsolete data), a copy back operation to another block, page, and/or bit, and an operation of erasing the unnecessary data by the block-wise at one time to implement the wear leveling.

The address allocator 208 may implement allocation of the logical address and the physical address in the block, page, or bit (cell)-wise of the memory. Therefore, data inserted into an appropriate physical block location, a page location, and/or a bit position may be allocated in order to implement the wear leveling. Additionally, the address allocator 208 may create a mapping table for mapping bits inserted into memory cells (for example, MLC, TLC, and the like) having a plurality of voltage state levels, and the like to appropriate voltage state levels.

The voltage controller 216 may, for example, apply to the memory cell a driving voltage level having a value equal to or higher than a previous in-cell write mode in order to express one or more bits. The application of the voltage may be performed based on the mapping table created by the address allocator 208. Further, the voltage controller 216 checks a voltage level of the memory cell corresponding to one or more bits written in the previous memory cell to decide a driving voltage level value to be applied to the memory cell. Herein, the cell-in write mode may indicate a value to count the number of cell-in write times in one erase cycle (alternatively, erase count).

The data file size analyzer 211 may decide the size of the inserted data file. Through the decision, the data file size analyzer 211 may, for example, decide whether the inserted data file has a smaller size than divided subpages.

Although not illustrated in FIG. 2, the flash translation layer 206 of the SSD controller 204 may include a hot data identifier. The hot data identifier 211 performs an operation of identifying and detecting data (hot data) which are frequently accessed and data (cold data) which are not frequently accessed to assist the implementation of the wear leveling.

Further, although not illustrated in FIG. 2, the SSD controller 204 may include a programming module (write and erase) and a reading unit for writing, erasing, and reading data with respect to the flash memory 205.

The SSD controller 204 may control all operations of the SSD. The SSD controller 204 may receive the logical address from the application 201 or the file system 202. The flash translation layer 206 of the SSD controller 204 may translate the received logical address into the physical address. The translated physical address may be transferred to a memory technology device layer 207 or the flash memory 205. The memory technology device layer 207 may represent an interface layer for supporting various flash memories or RAMs. Additionally, the memory technology device layer 207 may be an optional component.

The flash memory 205 may be constituted by a plurality of memory cells having a string structure as well known to those skilled in the art. An aggregate of the memory cells is generally designated as a cell array. The cell array of the flash memory 205 is constituted by a plurality of memory blocks. Each of the memory blocks 212 is constituted by a plurality of pages 213. Each page is constituted by a plurality of memory cells or data cells 214 sharing one word line. Herein, single bit data, multiple bit data, or triple bit data may be stored in one memory cell or data cell 214. For example, the memory cell in which the single bit data may be stored is designated as a single level cell (SLC), a memory cell in which the multi bit data may be stored is designated as a multi level cell (MLC), and a memory cell in which the triple bit data may be stored is designated as a triple level cell (TLC).

In an additional aspect of the present invention, each page 213 in the block 212 in the flash memory 205 may be constituted by a plurality of subpages 215. For example, when the size of the page 213 is 4 KB, four subpages 215 per 1 KB may be formed in one page 213.

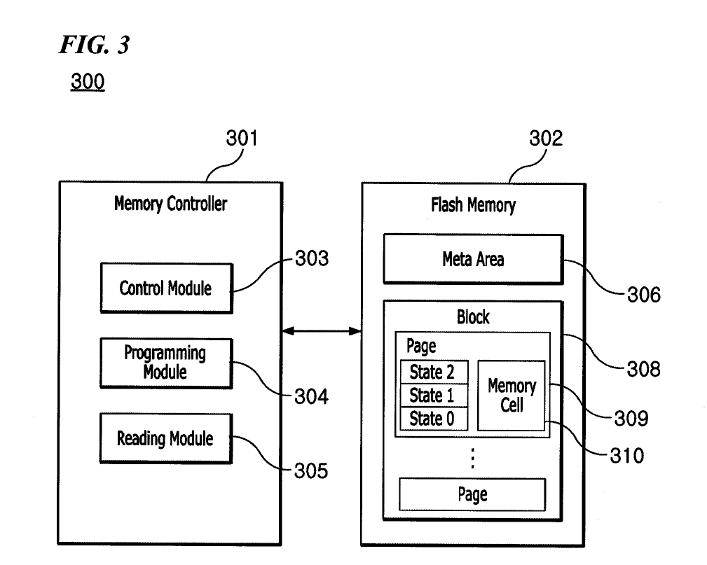

FIG. 3 is a diagram schematically illustrating a memory system 300 according to one aspect of the present invention.

As illustrated in FIG. 3, the memory system 300 may include a memory controller 301 and a flash memory 302.

The memory controller 301 may control all operations of the flash memory 302. The memory controller 301 may include a control module 303 for performing wear leveling, bit allocation, voltage control, and page division, a programming module 304 for performing the write and erase operations, and a reading module 305 for performing the read operation.

In one aspect of the present invention, the control module 303 may perform the wear leveling, the bit allocation, the voltage control, and the page division based on meta data stored in a meta area 306, and the like when receiving an operation request for the flash memory 302 from the host or application. Further, the control module 303 may control operations of the programming module 304 and the reading module 305.

In an aspect of the present invention, the control module 303 may determine an in-cell write mode based on the number of data write request times for the memory cell. The control module 303 may determine a driving voltage level value to be applied in order to express one or more bits in the memory cell based on the determined in-cell write mode. Further, the control module 303 may create a mapping table in which one or more bits are mapped to a high or equivalent level state from low state levels among state levels of the memory cell according to the in-cell write mode. The created mapping table may be stored in the flash memory 302 (for example, the meta area 306).

Moreover, the control module 303 may select, based on a plurality of predetermined factors, one of a technique of writing one or more information units in the memory cell at one time in one erase cycle by using states of the same number as the maximum number of states which may be expressed in the memory cell and a technique of writing one or more information units in one erase cycle in the memory cell multiple times by using states of the number smaller than the maximum number of the states which may be expressed in the memory cell. The selection may be determined based on factors such as an attribute of data, the size of the data file, a wear leveling state in the flash memory, and the like.

Furthermore, the control module 303 may divide a page 310 of the flash memory 302 into subpages. Further, the control module 303 may sequentially allocate divided inserted data (overwritten data) to the divided subpages. Herein, the sequentially allocated data may correspond to the same logical address. That is, the sequentially allocated data may represent the same file.

The allocation may be performed based on the size of data of which writing is requested. Additionally, the control module 303 may set and store state values of the respective subpages. The state values may include a valid state in which a final update value of the data is written, an obsolete state in which a value before an update request of the data is written, and an empty state in which the data is yet not written.

Wear leveling according to an additional aspect of the present invention may represent not inter-page wear leveling but in-page wear leveling or micro wear leveling. In more detail, generally, there are many cases in which bad blocks are generated when not a group of cells in the page wise but one or more cells are more than an abrasion threshold. Accordingly, in order to implement wear leveling in the cell wise (that is, in the bit level), the control module 303 may perform a change (for example, shift (alternatively, rotating, reversing, and/or scrambling)) of a bit position in the page or a change (for example, inversion) of a data value written in the bit position in the page.

Additionally, the control module 303 may determine a type of data to be written and determine a technique for writing respective data bits in one page based on the decided data type. In more detail, the control module 303 may determine the type (for example, file type (doc, xls, ppt, txt, pdf, way, mp3, jpg, zip, and avi)) of the data to be written. Information regarding the file type may be included in the writing request of the data, and the like. When the type of data to be written is determined, the control module 303 may select an appropriate technique among the micro wear leveling techniques (shifting, reversing, scrambling, and inversing) according to the determined data type, or determine whether to divide the subpages, the number of subpages to be divided, or an allocation technique of one or more bits depending on the state levels of the memory cell, based on a predetermined algorithm.

Further, the control module 303 may be implemented as firmware. For example, the ware control module 303 may be included in the flash translation layer (FTL). Herein, the flash translation layer is the system software that manages the erase/write/read operation in order to use the flash memory 302 like the hard disk as described above. The flash translation layer may perform subpage partitioning voltage control, mapping information management, bad block management, data preservation management in unexpected power interruption, abrasion level management, and the like.

The programming module 304 may write the data bits to be written in one page according to control of the control module 301. In more detail, the programming module 304 may apply the driving voltage level value for expressing one or more bits in the memory cell according to a voltage value decided by the control module 301. Further, the programming module 304 may sequentially write data in the divided subpages. Additionally, the programming module 304 may perform the erase operation of the memory cell in response to a subsequent writing request when all of a plurality of state levels of the memory cell are used. Further, the programming module 304 may perform the erase operation of the memory cell in response to the subsequent writing request when all subpages in the page are used. As described above, the programming module 304 may write data in a user area 307 of the flash memory 302 or erase data from the user area 307. When the write and/or erase operation is performed, the programming module 304 may change the meta data (for example, in-cell write information, erase count or write mode count) stored in the meta area 306 of the flash memory 302.

In one aspect of the present invention, the reading module 305 may read the data written in the user area 307 of the flash memory 302. The reading module 305 may read the data written in the user area 307 based on mapping information between the logical address and the physical address by referring to the data stored in the meta area 306. That is, the reading module 305 may analyze information read from the physical address as an appropriate logical address by referring to the write mode count, the in-cell write mode information, the voltage state level of the memory cell, the mapping information, and/or count information stored in the meta area 306.

The flash memory 302 according to one aspect of the present invention may include the meta area 306 and the user area 307.

In an aspect of the present invention, the meta area 306 may store the meta data (alternatively, control data) for managing the flash memory 302. The meta data may include in-cell write mode information, write mode count information, a mapping table, and the like. The meta area 306 may include one or more physical blocks constituted by a plurality of physical pages having a plurality of memory cells.

Additionally, the meta area 306 may be integrated in the user area 307. In this case, for example, the meta data such as the in-cell write mode information and/or count information will be stored in a page 309 or a block 308 of the user area 307. Additionally, the meta data may be stored in a header (not illustrated) of the page 309 or the block 308 of the user area 307.

The user area 307 may represent a data storage of a general flash memory. The user area 307 may include at least one physical block constituted by a plurality of physical pages having a plurality of cells.

As illustrated in FIG. 3, one page 309 of the user area 307 of the flash memory 302 may include the plurality of memory cells 310. Each of the memory cells 310 may express three or more different states according to the driving voltage level value. For example, when the memory cell 310 is the MLC, the memory cell 310 may express four different states. Further, when the memory cell 310 is the TLC, the memory cell 310 may express eight different states. In FIG. 3, three states (state 0, state 1, and state 2) are illustrated, but it will be apparent to those skilled in the art that three or more various states may be present through a set-up for the memory cell 310.

Additionally, although not illustrated in FIG. 3, one page 309 may be divided into the plurality of subpages.

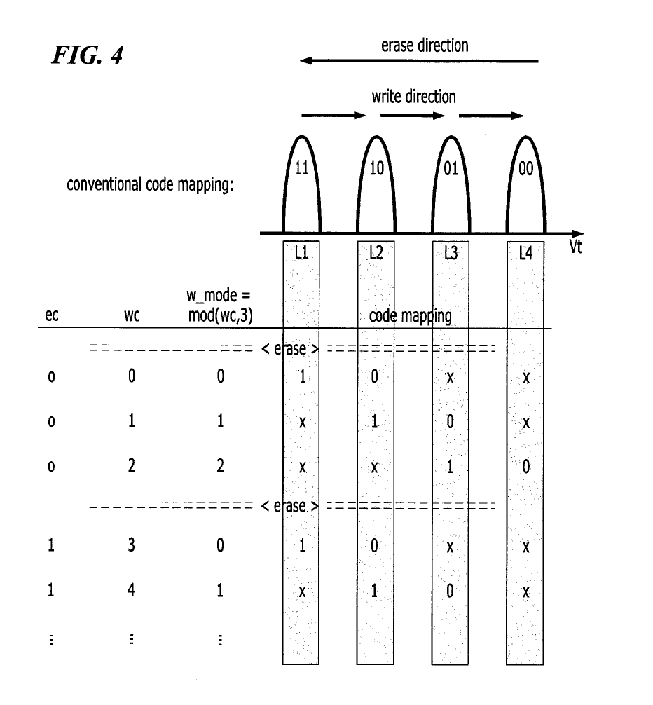

FIG. 4 exemplarily illustrates an overwrite technique in one cell of a memory device according to an aspect of the present invention.

In FIG. 4, as the memory cell, the MLC is described as an example. The MLC may express four different voltage level states. As illustrated in FIG. 4, a code mapping scheme in the MLC in the related art may write 2-bit values of ‘11’ in an L1 state, ‘10’ in an L2 state, ‘01’ in an L3 state, and ‘00’ in an L4 state. For example, when 2-bit data of 10 is intended to be written, driving voltage corresponding to the L2 state is applied, and as a result, data of ‘10’ may be written in the memory cell. The L1 to L4 states refer to different driving voltage values programmed to the memory cell.

As described above, in the mapping scheme in the related art, 2 bits may be written in one cell by one writing. In this case, when an overwrite request to the same memory cell is input, data according to the overwrite request needs to be written after erasing the corresponding memory cell. In other words, in the mapping scheme in the related art, only one writing may be permitted during one erase cycle.

In the case of the mapping scheme in the related art, since only one writing may be permitted in one erase cycle, there is a disadvantage in that the lifetime of the memory device may be decreased by increasing an abrasion degree of a specific cell of the memory device.

A technique for increasing the lifetime of the memory device (for example, flash memory) by minimizing the write and erase cycles is described below.

As illustrated in FIG. 4, a code mapping scheme according to an aspect of the present invention may permit one bit to be written three times in an example of the MLC. In more detail, in the memory cell which is in the empty state after the erasing operation, when the writing request is input, the value of 1 may be mapped to the L1 state of the memory cell and the value of 0 may be mapped to the L2 state. Next, when a subsequent writing request is input, the value of 1 may be mapped to the L2 state of the memory cell and the value of 0 may be mapped to the L3 state. When another subsequent writing request is input, the value of 1 may be mapped to the L3 state of the memory cell and the value of 0 may be mapped to the L4 state. Meanwhile, in FIG. 4 and a description given below, ‘X’ represents that the corresponding voltage level is not used for the data mapping.

Through the new mapping scheme, a maximum of three writing operations may be permitted during one erase cycle as compared with the mapping scheme in the related art. That is, data of 1 bit may be written through the L1 and L2 states, additional data of 1 bit may be written through the L2 and L3 states, and additional data of 1 bit may be written through the L3 and L4 states.

As illustrated in FIG. 4, according to an aspect of the present invention, three write counts wc or three write modes w_mode (alternatively, in-cell write mode) per erase count ec may be permitted. According to an exemplary embodiment of the present invention, the number of write modes (w_mode) may be determined based on a value of the ‘write count (mod ‘the total number of driving voltage level values of the memory cell−1’). In more detail, in the case of the MLC, the write mode w_mode may be determined as ‘wc (mod 3)’. In an aspect of the present invention, the in-cell write mode may be determined based on the number of data write request times in the memory cell. The in-cell write mode and the write mode in the specification are used to be exchanged with each other.

In an aspect of the present invention, while the write mode w_mode is 0, it is assumed that data of binary 1 is written in the memory cell illustrated in FIG. 4. In this case, driving voltage corresponding to the L1 state will be applied to the memory cell.

Herein, while the write mode is changed to the state in which the write mode is 1, when data to be written is binary 1, the memory controller 301 may determine to apply a voltage value of L2. Alternatively, when the data to be written is binary 0, the memory controller 301 may determine to apply a voltage value of L3. As such, when a high-level voltage value is applied to the memory cell, the value of 1 or 0 may be rewritten in the memory cell.

In another example, under a mapping table in FIG. 4, a current write mode is 1 and four same MLCs (for example, cell 1, cell 2, cell 3, and cell 4) exist and it is assumed that all voltage differences among L1, L2, L3, and L4 are 0.1 V. Further, it is assumed that data of 0, 1, 1, and 0 are written in four cells, respectively in a current state.

In such a state, when the subsequent write request is input, a count value of the write mode (for example, in-cell write mode) increases from 1 to 2. With a change of the in-cell write mode, data input according to a new code mapping relationship may be written. In more detail, it is assumed that in the subsequent write request, writing the data of 1, 0, 1, and 0 in four cells, respectively is requested. In this case, in the case of cell 1, since 0 of the L3 state in a previous write mode is written, voltage of L3 will be just required in order to write 1 in a new write mode (that is, 1 may be written without applying the voltage). In the case of cell 2, since 1 of the L2 state in the previous write mode is written, voltage of L4 will be just required in order to write 0 in the new write mode (that is, when voltage of L4 is applied to cell 2, the value of 0 may be rewritten to cell 2). Even in the case of cells 3 and 4, when respective voltage is applied, the values of 1 and 0 may be rewritten in cells 3 and 4 by a scheme which is the same as the aforementioned scheme.

As a result, in techniques according to an aspect of the present invention, the number of erase times for the memory cell (in the case of the MLC) is maximally ⅓ smaller than that in the techniques in the related art. Therefore, according to an aspect of the present invention, since a plurality of writing operations in one cell may be permitted in one erase cycle, the lifetime of the memory device (for example, flash memory) may increase.

The aforementioned embodiment is an example and according to another exemplary embodiment of the present invention, an operation mode the memory cell and the number of bits stored in one memory may be variously configured. That is, in the memory system according to another embodiment of the present invention, one or more information units may be written multiple times in one memory cell within one erase cycle by using states of a smaller number than the maximum number of states which may be expressed in one memory cell according to the operation mode of the memory cell. For example, when the memory cell is the TLC, a total of eight different states may be expressed and one TLC memory cell may write a maximum of 3 bits. In this case, the memory system according to an exemplary embodiment of the present invention may allocate the data of 1 bit or 2 bits to be written in one TLC memory cell. According to an exemplary embodiment of the present invention, when one bit is controlled to be written in one TLC memory cell, the memory system may allocate different voltage state levels for each in-cell write mode in order to express one bit as shown in Table 1 given below.

TABLE 1

| | Voltage | Voltage | Voltage | Voltage | Voltage | Voltage | Voltage | Voltage |
|---|---|---|---|---|---|---|---|---|
| | state | state | state | state | state | state | state | state |
| | level 0 | level 1 | level 2 | level 3 | level 4 | level 5 | level 6 | level 7 |
| Write | 1 | 0 | X | X | X | X | X | X |
| mode 1 | | | | | | | | |
| Write | X | 1 | 0 | X | X | X | X | X |
| mode 2 | | | | | | | | |
| Write | X | X | 1 | 0 | X | X | X | X |
| mode 3 | | | | | | | | |
| Write | X | X | X | 1 | 0 | X | X | X |
| mode 4 | | | | | | | | |
| Write | X | X | X | X | 1 | 0 | X | X |
| mode 5 | | | | | | | | |
| Write | X | X | X | X | X | 1 | 0 | X |
| mode 6 | | | | | | | | |
| Write | X | X | X | X | X | X | 1 | 0 |
| mode 7 | | | | | | | | |

As shown in Table 1, in the case of allocating 1 bit to one TLC memory cell, one TLC bit may use 7 different write modes and the memory system 100 may rewrite data in one memory cell maximally seven times without the erasing operation.

Further, in another exemplary embodiment of allocating the bit of 1 to one TLC memory cell, not X but the value of 1 may be allocated to a level before a level at which the value of 0 is written. In this case, when an input of 1 is input, the value of 1 may be written in the same cell without an increase (shift) of the voltage level. The bit allocating method for the exemplary embodiment is expressed in Table 2 given below.

TABLE 2

| | Voltage | Voltage | Voltage | Voltage | Voltage | Voltage | Voltage | Voltage |
|---|---|---|---|---|---|---|---|---|
| | state | state | state | state | state | state | state | state |
| | level 0 | level 1 | level 2 | level 3 | level 4 | level 5 | level 6 | level 7 |
| Write | 1 | 0 | X | X | X | X | X | X |
| mode 1 | | | | | | | | |
| Write | 1 | 1 | 0 | X | X | X | X | X |
| mode 2 | | | | | | | | |
| Write | 1 | 1 | 1 | 0 | X | X | X | X |
| mode 3 | | | | | | | | |
| Write | 1 | 1 | 1 | 1 | 0 | X | X | X |
| mode 4 | | | | | | | | |
| Write | 1 | 1 | 1 | 1 | 1 | 0 | X | X |
| mode 5 | | | | | | | | |
| Write | 1 | 1 | 1 | 1 | 1 | 1 | 0 | X |
| mode 6 | | | | | | | | |
| Write | 1 | 1 | 1 | 1 | 1 | 1 | 1 | 0 |
| mode 7 | | | | | | | | |

In another exemplary embodiment of the present invention, the TLC memory cell may be configured to express 8 different states and the memory system 100 according to an exemplary embodiment of the present invention may be configured to express two bits in one TLC memory cell.

Additionally, in the specification, in the specification, a scheme that writes data is primarily described, but even in the case of reading data, the data may be read according to the aforementioned mapping scheme. For example, in an example of Table 2, when the current write mode is 4 and the reading module or the memory controller reads the voltage level state of the corresponding memory cell as 4, the reading module or the memory controller may read that data written or stored in the corresponding memory cell is 0.

In another embodiment of the present invention, a method in which the memory system 100 allocates two bits to one TLC memory cell may be shown in Table 3 given below.

TABLE 3

| | Voltage | Voltage | Voltage | Voltage | Voltage | Voltage | Voltage | Voltage |
|---|---|---|---|---|---|---|---|---|
| | state | state | state | state | state | state | state | state |
| | level 0 | level 1 | level 2 | level 3 | level 4 | level 5 | level 6 | level 7 |
| Write | 11 | 10 | 01 | 00 | X | X | X | X |
| mode 1 | | | | | | | | |
| Write | X | X | X | X | 11 | 10 | 01 | 00 |
| mode 2 | | | | | | | | |

The aforementioned exemplary embodiments using the TLC memory cell and/or the MLC memory cell are examples. According to yet another exemplary embodiment of the present invention, the maximum number of maximum states (that is levels) which may be expressed in one memory cell is 8. In this case, data is configured to be written in one memory cell by using the number of states which is smaller than the number of maximum states which may be expressed in one memory cell and performing an in-cell overwriting operation in the memory cell at least one time without the erasing operation by using different in-cell write modes may be included in the claims of the present invention.

Additionally, in the specification, a scheme that writes data is primarily described, but even in the case of reading data, the data may be read according to the aforementioned mapping scheme. For example, in an example of Table 3, when the reading module or the memory controller reads the voltage level state of the corresponding memory cell as 2, the reading module or the memory controller may read that data written or stored in the corresponding memory cell is 01.

In another exemplary embodiment of the present invention, memory cells having different operation states may be together used in one memory device constituting the memory system. For example, at least some memory cells may be constituted by the MLC memory cell and some other memory cells may be constituted by the TLC memory cells in the memory device constituting the memory system according to an exemplary embodiment of the present invention. In this case, the memory system may set the number of states for expressing one or more information units (for example, bits) in the memory cell to be smaller than the maximum number of states which may be expressed in the memory cell for each memory cell.

When a memory cell according to an additional aspect of the present invention is the TLC, two writing operations in one cell by a 2-bit wise in one erase cycle may be permitted. Furthermore, when the memory cell is the TLC, one writing operation in one cell by the 2-bit-wise and three writing operations in one cell by a 1-bit-wise may be permitted in one erase cycle.

When the memory cell according to the additional aspect of the present invention includes, for example, three voltage state levels, two writing operations in one cell by the 1-bit-wise may be permitted.

Additionally, since one cell may implement all levels of the MLC and the TLC, the MLC and the TLC (alternatively, cells having different levels) may be alternately implemented. In this case, an additional wear leveling effect may be achieved.

Moreover, in an aspect of the present invention, the memory controller 301 may express one or more information units by using states of a smaller number than the maximum number (for example, 14=2(SLC)+4(MLC)+8(TLC)) of states which may be expressed by combining the SLC, the MLC, and the TLC. In more detail, a combination (that is, multiple cells are gathered to express one or more information units) of the memory cells having various state levels, such as the SLC, the MLC, and the like may also be included in the scope of the present invention.

Furthermore, when data is written in one cell a predetermined number of times by a writing method according to an aspect of the present invention, at least one of an operation of erasing the corresponding cell and/or an operation of implementing the same writing method by determining a different page may be performed.

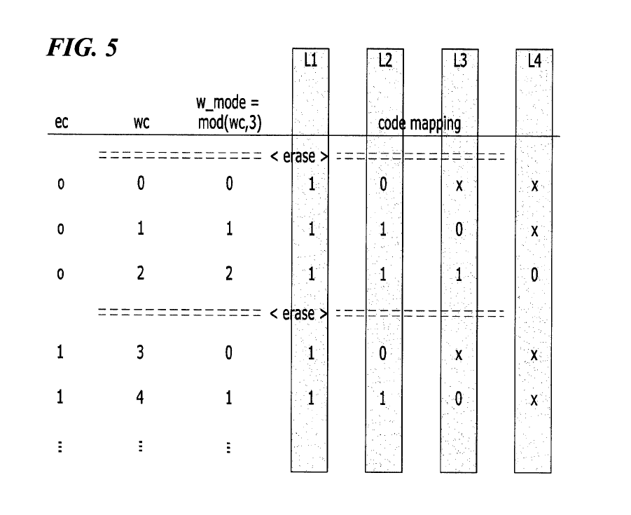

FIG. 5 exemplarily illustrates an overwrite technique in one cell of a memory device according to another aspect of the present invention.

The overwrite technique illustrated in FIG. 5 is different from the overwrite technique illustrated in FIG. 4 in the mapping scheme. In more detail, the overwrite technique illustrated in FIG. 5 may be configured so that the value of 1 may be configured to be mapped to all voltage state levels lower than the voltage state level having the value of 0.

Through the mapping technique, in respective write stages, only when data to be stored has the value of 0, a voltage value may be shifted.

As illustrated in FIG. 5, a code mapping scheme according to an aspect of the present invention may permit one bit to be written three times in an example of the MLC. In more detail, in the memory cell which is in the empty state after the erasing operation, when the writing request is input, the value of 1 may be mapped to the L1 state of the memory cell and the value of 0 may be mapped to the L2 state. Next, when a subsequent writing request is input, the value of 1 may be mapped to the L2 state of the memory cell and the value of 0 may be mapped to the L3 state. When a subsequent writing request is input, the value of 1 may be mapped to the L1, L2, and L3 states of the memory cell and the value of 0 may be mapped to the L4 state.

In an aspect of the present invention, while the write mode w_mode is 0, it is assumed that data of binary 1 is written in the memory cell illustrated in FIG. 5. In this case, the driving voltage corresponding to the L1 state will be applied to the memory cell.

Herein, while the write mode is changed to the state in which the write mode is 1, when data to be written is binary 1, the voltage level state L1 to which the value of 1 in write mode 1 is mapped and the voltage level state L1 to which the value of 1 in write mode 0 is mapped are the same as each other, and as a result, the memory controller 301 may write the value of 1 in write mode 1 without shifting the voltage. Alternatively, when the data to be written is binary 0, the memory controller 301 may determine to apply a voltage value having the value of L3.

In other words, when according to the subsequent writing request, writing data 1 is requested, the value of 1 may be rewritten in the corresponding memory cell without applying the voltage value.

Accordingly, through the aforementioned technique, stress in the floating gate of the memory cell which is generated in applying the voltage may be reduced. Therefore, (in the case of the MLC), three consecutive overwriting operations in the 1-bit-wise are permitted in one cell and voltage having a shifted level value is applied only when the value of 0 is requested to maximize the lifetime of the memory cell.

Moreover, it will be apparent to those skilled in the art that the techniques illustrated in FIG. 5 may also be applied to the TLC and a memory cell having a plurality of different levels.

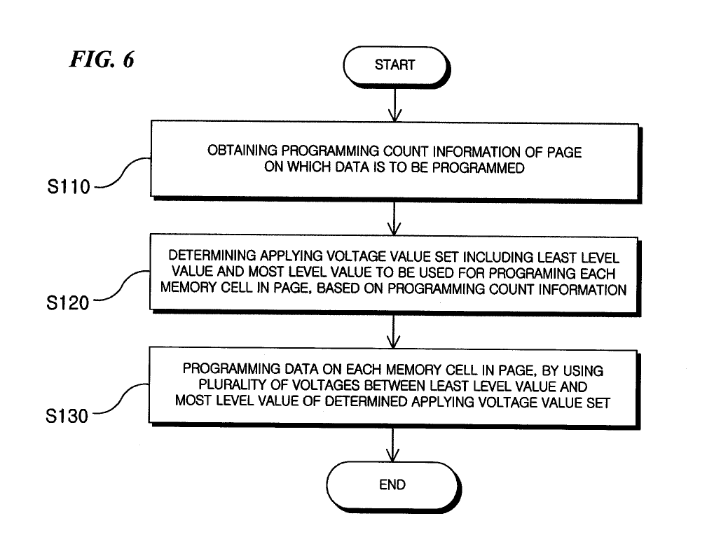

FIG. 6 is a flowchart of a data processing method of a memory according to an aspect of the present invention. The method illustrated in FIG. 6 may be performed by, for example, the memory controller 301. It will be apparent to those skilled in the art that additional steps other than steps illustrated in FIG. 6 may also be included in the method and some steps may be omitted.

First, the memory controller obtains programming count information of a page on which data is to be programmed (S110). In an aspect of the present invention, the programming count information is used as a concept including information on the number of times which may be used as various names such as information on a writing count of the corresponding page and information on the number of writing request times of a memory cell. The programming count information is increased by one by the writing request (alternatively, programming request) of the data for the corresponding page.

Next, the memory controller determines a driving voltage value set including a least level value and a highest level value to be programmed in each memory cell in the page, based on the obtained information on the programming count information (S120). In an aspect of the present invention, the memory controller may determine an in-cell write mode based on the programming count information. In this case, the in-cell write mode may be determined as ‘the programming count information mod (a total number of −1 of the driving voltage level value of the memory cell’)’. For example, in the case of MLC, the ‘total number of the driving voltage level value of the memory cell’ is 4, and as a result, the in-cell write mode may be determined by the ‘programming count information mod 3’.

In an aspect of the present invention, the memory controller shifts at least one of the least level value and the highest level value of the driving voltage value set in response to an increase in the programming count information.

According to an aspect of the present invention described with reference to FIG. 4, the memory controller may together shift the least level value and the highest level value in response to the increase in the programming count information. In this case, the least level value and the highest level value may be set to have a predetermined level difference at all times. For example, when the least level value and the highest level value allocated to the memory cell of the corresponding page are L1 and L2, respectively, the memory controller may shift the least level value and the highest level value to L2 and L3 in response to the increase in the programming count information, respectively.

Further, according to another aspect of the present invention described with reference to FIG. 5, the memory controller may shift only the highest level value in response to the increase in the programming count information. For example, when data ‘0’ is mapped to the highest level value, only the driving voltage level value for writing the data ‘0’ may be changed in response to the increase in the programming count information. Further, data ‘1’ may be set to be mapped to all lower voltage levels than the voltage level mapped to the data ‘0’. That is, when the least level value and the highest level value allocated to the memory cell of the corresponding page are L1 and L2, respectively, the memory controller may change the least level value and the highest level value to L1 and L3 in response to the increase in the programming count information, respectively. In this case, the memory controller may refer to a mapping relationship between bits and the voltage level values in a previous write mode and/or a mapping relationship between bits and the voltage level values in a current write mode. The memory controller may decide the driving voltage level value to be applied (that is, the shift voltage value) according to the voltage level value with the bits written in the previous write mode and the value of the data requested in the current write mode.

Next, the memory controller programs the data on each memory cell in the page by using a plurality of voltages between the least level value and the highest level value of the decided driving voltage value set (S130). The memory controller may apply the driving voltage level value for expressing one or more bits in the memory cell based on the determined in-cell write mode. The application may represent that a driving voltage value which is larger than or equal to the driving voltage value in the previous in-cell write mode for expressing one or more bits is applied to the memory cell.

In an aspect of the present invention, the number of states for expressing one or more information units in the memory cell may be smaller than the maximum number of states which are expressible in the memory cell. In more detail, the number of states of the memory cell used in one writing operation may be smaller than the maximum number of states which are expressible in the memory cell.

For example, in the case of the TLC as the memory cell, the maximum number of states which are expressible in the memory cell is 8. Accordingly, the number of states of the memory cell used in one writing operation may be smaller than 8 (for example, two states for expressing 1 bit or four states for expressing 2 bits).

Meanwhile, according to another aspect of the present invention, as described below, each page of the memory may include a pilot cell at a predetermined position and the memory controller may perform reading of the data by using the pilot cell. In more detail, in one page, the pilot cell at the predetermined position and the data cell where the data is programmed may be included. A threshold voltage for reading the data programmed in the data cell may be written on the pilot cell.

More particularly, the memory controller may program the threshold voltage between the least level value and the highest level value which are shifted in response to the increase in the programming count information in the pilot cell. In this case, a threshold voltage value programmed in the pilot cell is shifted in response to the increase in the information on the number of programming time. Next, the memory controller reads the voltage value written on the pilot cell in response to the reading request of the data written on the page. In addition, the memory controller sets a read voltage value for reading the data cell by referring to the read voltage value of the pilot cell and may read the data of the data cell based on the set read voltage value.

The memory controller may shift the threshold voltage value written on the pilot cell in response to the shift of the driving voltage value set used in the programming of the data cell. The memory controller may read the data of the data cell based on the reading voltage obtained from the pilot cell. In more detail, the memory controller may read the data as the data ‘0’ when the voltage of the data cell is larger than the reading voltage and as the data ‘1’ when the voltage of the data cell is smaller than the reading voltage. As such, according to the aspect of the present invention, the memory controller need not refer to a separate programming count when reading the data programmed in the data cell and may read the data by immediately obtaining the read voltage value for the data cell from the pilot cell of the corresponding page.

Next, according to yet another aspect of the present invention, the memory controller may apply the aforementioned overwriting method in one cell to only the small data in which the size of the data to be programmed corresponds to a predetermined reference or less. As an example, when the memory cell is the MLC, the memory controller performs the in-cell overwrite for the corresponding page only when the size of the data is smaller than a half of the size of the page. In this case, the memory controller may overwrite the data on the corresponding page as it is when an overwrite request (alternatively, an update request) for the corresponding data is received.

In more detail, the memory controller determines the size of the programming-requested data and determines whether the determined size of the data is smaller than a half of the size of the page. If the size of the data is smaller than a half of the size of the page, the memory controller programs the data in each memory cell as 1 bit information using the aforementioned least level value and the highest level value. When the overwrite request for the programmed data is received, the memory controller shifts the least level value and the highest level value for the corresponding page as described above and reprograms the data on each memory cell of the page by using the shifted least level value and the highest level value. In this case, the data reprogrammed in each memory cell may be updated data in the overwrite request. As such, according to the aspect of the present invention, new data different from the data stored in a specific page is not programmed, but the data prestored in the corresponding page is updated and reprogrammed, and as a result, a logic address (alternatively, log data) mapped to the data in the corresponding page needs not to be changed.

Meanwhile, the mapping method and the sequence of 0 and 1 in the present invention are just exemplified, and the sequence of 0 and 1 in this specification may be varied. In more detail, 0 and 1 may be reversely mapped.

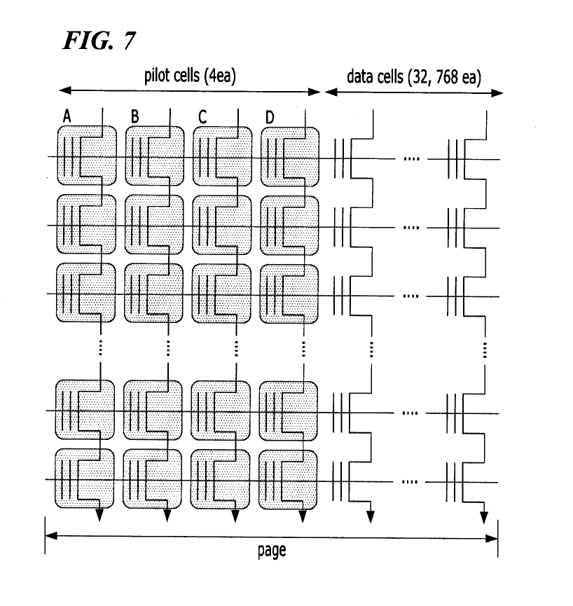

FIG. 7 exemplarily illustrates a data block including pilot cells according to an aspect of the present invention.

As described above, memories such as a flash memory may use arrays of analog memory cells for storing the data. Each analog memory cell may store an amount of analog values such as a charge amount or voltage for expressing information stored in the cell. For example, each memory cell holds a predetermined amount of charge. The range of the analog values may be generally divided into predetermined regions and each region may correspond to one or more data bit values. For example, SLC may be divided into two regions and cells having a plurality of levels such as MLC may be divided into four or more regions.

In the memory such as the SSD, the data may be written in the analog memory by writing a nominal analog value corresponding to required bits. Since the analog values may have various statistic distributions, selection for the nominal values used for programming different levels may have a large effect on performance of the memory cell array.

When the nominal values are adjacent to each other, a probability that the error occurs in reading the memory cell is high. On the contrary, when the nominal values have a large difference, a dynamic range of the analog values in the memory cell array may be increased. In this case, more power may be consumed and the programming speed of the memory cell may be lowered.

Since the nominal values in each cell has an attribute which may be temporally and spatially changed, using a predetermined value in reading and writing may have a bad effect on performance of the memory such as a bit error rate (BER).

When more voltage level states in one cell are present, a probability that the error occurs may be higher due to a characteristic of the analog voltage in writing and reading the data.

In this situation, the present invention proposes a programming method using predetermined nominal values in a pilot cell positioned in a predetermined region of the page. Through the programming method, analog voltages read in the pilot cells may be used for compensating for an error and a change of the voltages in the adjacent data cells.

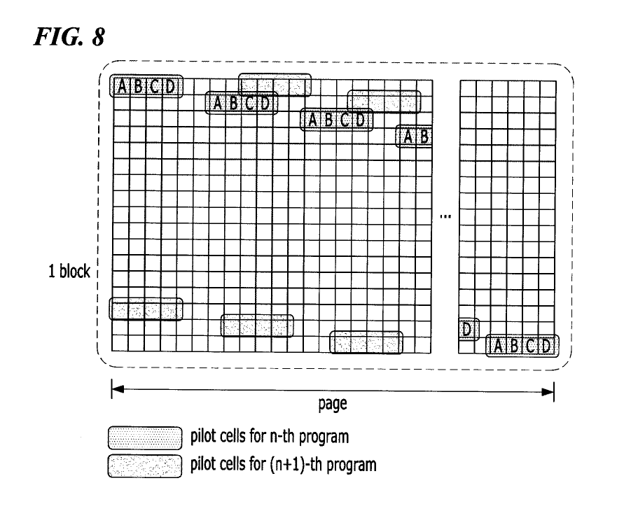

As illustrated in FIG. 7, one page in the block of the memory according to an aspect of the present invention may be constituted by one or more (for example, four) pilot cells and a plurality of (for example, 32,768) data cells. In FIG. 8, four pilot cells are exemplarily illustrated, but the pilot cells more than or less than the four pilot cells may be included in the scope of the present invention.

In FIG. 7, the SSD constituted by the MLC having four nominal values is exemplified. In each page, four pilot cells represented by A, B, C, and D may be predetermined. With respect to the respective pilot cells, pilot cell A, pilot cell B, pilot cell C, and pilot cell D may be allocated to (with?) 11, 10, 00, and 01, respectively. The pilot cells may have unique nominal values (that is, reference voltage values), respectively.

The nominal values corresponding to the pilot cells A, B, C, and D, respectively are fixed values, differently allocated to each page, or may be changed by various methods in order to implement the wear leveling. Further, the pilot cells A to D may be disposed in various positions in the page. For example, the pilot cells may be positioned in front, in the middle, or at the end of the page. The arrangement of the pilot cells may be determined based on types of pages, a programming count, and a random method.

By using the pilot cells, the data may be programmed by using the predetermined nominal values in the pilot cells arranged at the predetermined position in the page. Next, the reading or writing operation for the data cell may be performed by referring to the values of the pilot cells.

FIG. 8 exemplarily illustrates a change in arrangement of pilot cells according to a programming count and a page according to an aspect of the present invention.

As illustrated in FIG. 8, the pilot cells may be arranged at various positions based on the programming count and/or the page. Through the placement at various positions, the pilot cells may represent more useful values in providing reference to the data cells. Additionally, the placement at various positions may achieve even a wear leveling effect in the page.

According to an aspect of the present invention, the memory controller 201 writes the data by applying the voltage values to the pilot cells and thereafter, reads the pilot cells before writing the data in the data cell or reading the data to determine a voltage value to be used for writing or reading the data in the data cells.

According to an aspect of the present invention, the memory controller 201 may write the values in the pilot cells and thereafter, read the analog voltage values for the pilot cells. In the specification, in general, programming may include a process of re-reading voltage for validation.

Instead of the reading process for the validation, more accurate voltage values may be read by using higher resolution than voltage steps used for the programming. For example, when the value of ‘00’ is written in pilot cell D, voltage of 5 V may be written. However, when the corresponding cell is read, voltage of 4.7 V may be read. An opposite situation may also occur.

In this situation, at the programming time in the data areas, the writing operation may be performed by using the calculated nominal values in association with the reading voltages in the pilot cells. That is, as described above, when the nominal values in the reading process do not reach the desired reference voltage value (writing 5 V and reading 4.7 V), the voltage (for example, 0.3 V) by a difference between the voltage value when writing and the voltage value when reading may be considered in programming the data cell. That is, the data cell may be written by voltage of 5.3 V when being programmed. In this case, in reading the data cell, when the reference voltage value uses 5 V, more accurate reading may be performed.

On the contrary, when the nominal values in the reading process exceed the desired reference voltage value (writing 5 V and reading 5.3V), the voltage (for example, −0.3V) by a difference between the voltage value while writing and the voltage value while reading may be considered in programming the data cell. That is, the data cell may be written by voltage of 4.7 V when being programmed. In this case, in reading the data cell, when the reference voltage value uses 5 V, more accurate reading may be performed.

The technique may be based on an assumption that sensitivity and responsiveness for voltages of the cells are similar in one page. That is, other variables which influence a wear level, a temperature, and sensitivities of the cells may have a similar characteristic to the programming in the same page. Therefore, an optimal nominal value may be determined and maintained due to programming using the feed-back from the pilot cells. Through the process, since the feed-back from the pilot cells is reflected to perform programming in the programming process, the reading process may be simply performed by using a predetermined reference voltage value without a particular calculating operation.

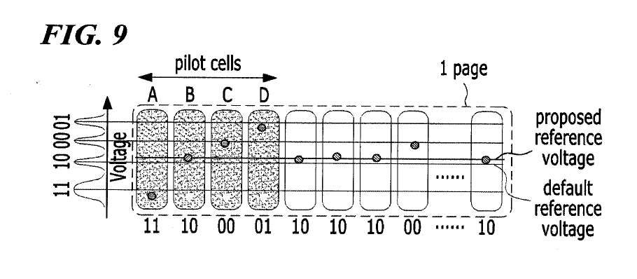

FIG. 9 exemplarily illustrates a reading method using pilot cells in a page according to an aspect of the present invention.

The memory controller 201 may perform programming for a data region by using predetermined nominal values used in the pilot cells without reflecting a feed-back which is referred in the pilot cells. That is, a page including the pilot cells and data cells may be programmed by using the same nominal values which are given. Instead, in a reading process, the memory controller 201 first reads the pilot cells and calculates threshold voltage values to be used for reading the data cells by referring to reading analog voltage values in the pilot cells.

FIG. 9 exemplarily illustrates a process for determining reading voltage values for data cells by first referring to the reading voltage values of the pilot cells in the reading process.

Respective pilot cells A, B, C, and D may be programmed by using nominal values (reference voltage values) according to ‘11’, ‘10’, ‘00’, and ‘01’, respectively. Voltage values which may be read in the programmed cells are represented by circles in FIG. 9. For example, as illustrated in FIG. 9, in the case of pilot cell A in which the value of ‘11’ is written, the voltage value may be read as a voltage value lower than the reference voltage value. Further, in the case of pilot cell B in which the value of ‘10’ is written, the voltage value may be read as a voltage value higher than the reference voltage value.

The reading voltage values for the pilot cells may be used as new reference voltage for the corresponding page. That is, in the case of a voltage level for reading the value of ‘10’, as illustrated in FIG. 9, not a voltage level value (default reference voltage) used in writing the value of ‘10’ but a voltage level value (proposed reference voltage) actually measured in reading pilot cell B may be used as a voltage level value for reading the data cells in the corresponding page.

Therefore, the reading process using the pilot cells in such a scheme may cause less reading errors than the existing reading process.

In an additional aspect of the present invention, the specification presents multiple pilot cells for the nominal values in one block, but alternatively, analog voltage values or nominal values are averaged in a block to be calculated or averaged according to a time to be calculated. Furthermore, since the analog values may be stored in a temporary memory such as a DRAM, a more rapid data access may be achieved.

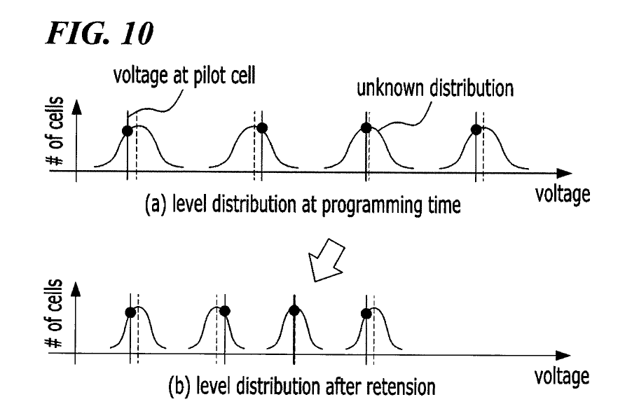

FIG. 10 exemplarily illustrates a change in threshold voltage after data programming.

When a predetermined time elapsed after data is programmed, distribution of the analog voltage values may be changed as illustrated in FIG. 10. In such a situation, a method in which the nominal values are adaptively defined with respect to the respective pages may be considered. Since the method considers different response characteristics of the cells, the method may have an advantage in terms of error occurrence and power consumption.

In more detail, the nominal voltage values may be adaptively selected during the data programming. Next, the voltage values may be stored as parameter to be used for reading the storage. The voltage values need to be stored as different parameter values in the respective pages. However, the parameters may be vast overhead in terms of the storage. That is, a separate vast space for allocating the parameter needs to be provided.

As technical features according to an aspect of the present invention associated with FIGS. 8 and 9, the data for the data cell may be efficiently read by referring to the analog voltage values for the pilot cells without requiring the separate space for storing the parameters.

Therefore, according to an aspect of the present invention, as illustrated in FIG. 10, when a pilot voltage level is determined by previously referring to the pilot cells, an appropriate threshold voltage value may be found without determining the response characteristics of the respective cells even though the voltage level is changed after the data programming. That is, when the pilot cells are used, more robust threshold voltage values may be generated without wasting a storage space.

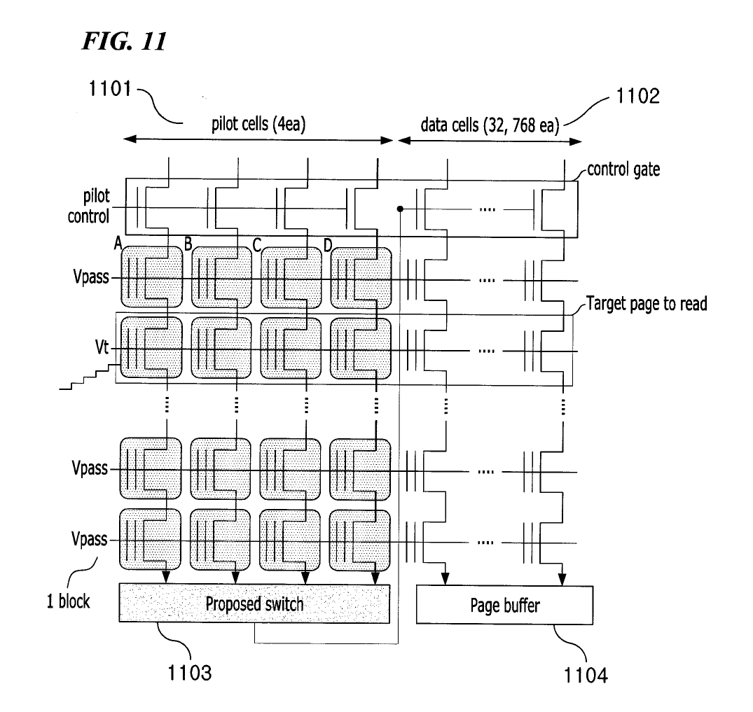

FIG. 11 exemplarily illustrates a voltage reading mechanism using pilot cells according to an aspect of the present invention.

FIG. 11 illustrates a plurality of cell arrays having a plurality of columns and rows of memory cells in one block. The memory cells illustrated in FIG. 11 are connected with each other in a specific array configuration. The array configuration of the memory cells is exemplary and other types of memory cells or other array configurations may also be included in the scope of the present invention.

As described above, a value stored (alternatively, written) in the memory cell may be read by measuring threshold voltage Vt of the cell. The reading threshold voltage may represent the quantity of charges stored in the memory cell.

As illustrated in FIG. 11, for example, one page may include 4 pilot cells 1401 and 32768 data cells 1402. Each of the memory cells includes a floating gate transistor. The pilot cells 1401 and the data cells 1402 (that is, gates of transistors of the cells) in one page share the same word line. Further, sources of transistors in respective columns may be connected to each other by bit lines. In the case of a NOR cell, the source may be directly connected to the bit lines and in the case of a NAND cell, the bit line may be connected to a string of a floating gate.

In FIG. 11, since a case of an MLC is described as an example, 4 different nominal values may be present. 4 different nominal values may be used to be written in pilot cells A, B, C, and D, respectively.

In an aspect of the present invention, an exemplary data block may further include a switch 1403 and/or a page buffer 1404. The switch 1403 may be disposed in a path from drains of the pilot cells to the sources of the data cells.

A target page to be read may be determined according to a data reading request. Step voltage may be applied to the target page to be read. The memory controller 201 or the reading module 205 applies the step voltage to the gate (that is, the word line to which the cell is connected) of the cell to read threshold voltage Vt of a specific memory cell. This may be implemented by checking whether drain current of a specific cell is more than the threshold voltage Vt. That is, the memory controller 201 or the reading module 205 applies the step voltage to the word line which the specific cell accesses to determine a minimum gate voltage value in which the drain current is more than the threshold voltage Vt.

As illustrated in FIG. 11, the memory controller 201 or the reading module 205 applies the step voltage to the word line of the target page to measure reading threshold voltage values of the pilot cells 1401 in the target page. That is, when the threshold voltage Vt corresponding to the pilot cell (for example, pilot cell A) in the target page has exceeded, the switch 1403 is closed, and as a result, current may flow to the data cell 1402 in the corresponding page.

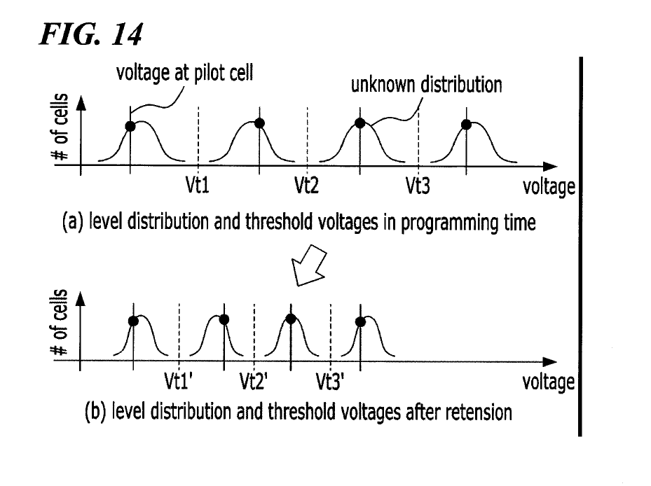

FIG. 14 exemplarily illustrates a data cell reading technique using a switch according to an aspect of the present invention.

As illustrated in FIG. 14, the step voltage may be input into the word line for the target page by the memory controller 201 or the reading module 205. When the step voltage passes through the threshold voltage Vt corresponding to pilot cell A, a switch for a control gate may be driven. As a result, current flows to the bit lines of the data cells and the data cells may be read according to an adaptive threshold voltage value determined by pilot cell A.

Pilot cells B, C, and D may also be sequentially implemented in the same scheme as pilot cell A through different threshold voltage values at different timings.

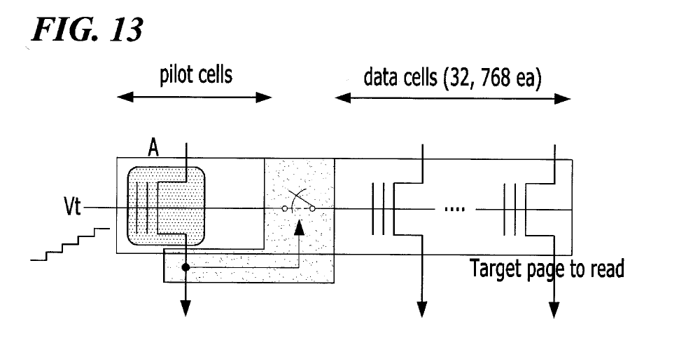

FIG. 13 exemplarily illustrates a data cell reading technique using a switch according to an aspect of the present invention.

As illustrated in FIG. 13, drain voltage of the pilot cell may be directly connected to the data cell by the switch for accessing the word line for the data cell. According to an aspect of the present invention, when the step voltage passes through the threshold voltage Vt corresponding to pilot cell A, the switch does not allow the current to flow to the control gate but allows the current to directly flow to the gates of the data cells. Therefore, the change in nominal values may also be automatically reflected on the data cell.

According to the schemes, the change in threshold voltage values may be directly reflected on the data cells through the pilot cells. The adaptive implementations do not require additional calculation to the existing mechanism.

In an additional aspect of the present invention, in reading the data for the data cell, the pilot cells are grouped to be used in order to achieve additional robustness. That is, a plurality of pilot cells may be used with respect to the respective nominal values. A group of the pilot cells may be commonly used with respect to one data block or one page.

FIG. 14 exemplarily illustrates a change in threshold voltage after data programming.

When a threshold voltage level for the data cell is determined by previously referring to the pilot cells, an appropriate threshold voltage value may be found without determining the response characteristics of the respective cells even though the voltage level is changed after programming the data. As a result, when the pilot cells are used, more robust threshold voltage values may be generated without wasting the storage space.

As illustrated in FIG. 14, level distribution of the threshold voltage values at a programming time may be changed as illustrated in FIGS. 14(a) to 14(d) as the time elapses. However, the technique according to an aspect of the present invention may find the optimal threshold voltage value for the data cell through the voltage value read in the pilot cell in spite of the change in threshold voltage values. That is, according to an aspect of the present invention, a reading error probability of the data cell due to the change in threshold voltage values may be reduced.

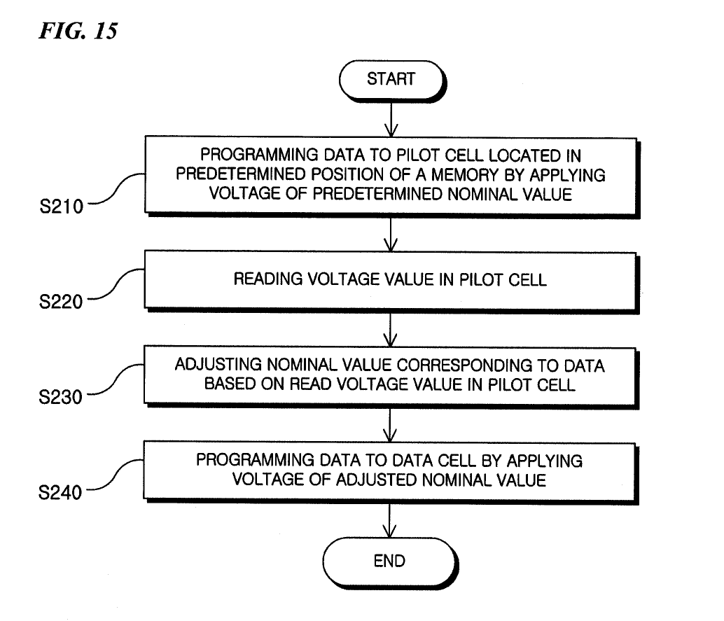

FIG. 15 is a flowchart of a data processing method of a memory according to an aspect of the present invention. It will be apparent to those skilled in the art that additional steps other than steps illustrated in FIG. 15 may be included in the method and some steps may be omitted.

As illustrated in FIG. 15, the memory controller applies voltage of a predetermined nominal value to a pilot cell at a predetermined position in the memory to program data (S310). According to an aspect of the present invention, the pilot cell is positioned within the same block or page as the data cell. Further, the pilot cell corresponds to each of one or more nominal values used for programming the memory. According to an aspect of the present invention, the pilot cell includes a plurality of cells corresponding to a plurality of nominal values used for the memory programming, respectively.

Next, the memory controller reads the written voltage value of the pilot cell (S320). In this case, the memory controller may read the voltage value of the pilot cell with higher resolution than the voltage step among the respective data for programming. For example, when the nominal value for each data for programming has a voltage step of 1 V, the memory controller may read the voltage value of the pilot cell with resolution of 0.2 V which is a higher resolution than an interval of 1 V.

Next, the memory controller corrects the nominal value corresponding to the data of the pilot cell based on the voltage value of the read voltage of the pilot cell (S330). In this case, the memory controller calculates a difference value between the read voltage value of the pilot cell and a predetermined nominal value and adds the calculated difference value to the predetermined nominal value to obtain the adjusted nominal value. According to another aspect of the present invention, the memory controller calculates a ratio between the read voltage value of the pilot cell and the predetermined nominal value and scales the predetermined nominal value based on the calculated ratio to obtain the adjusted nominal value.

The memory controller programs the data to the data cell of the memory by using the adjusted nominal value (S340).

Meanwhile, according to an aspect of the present invention, the memory controller may obtain information on the number of erase times of a block or the number of write times of a page at which the pilot cell is positioned. The memory controller may shift the position of the pilot cell based on the information on the number of erase times or the information on the number of write times.

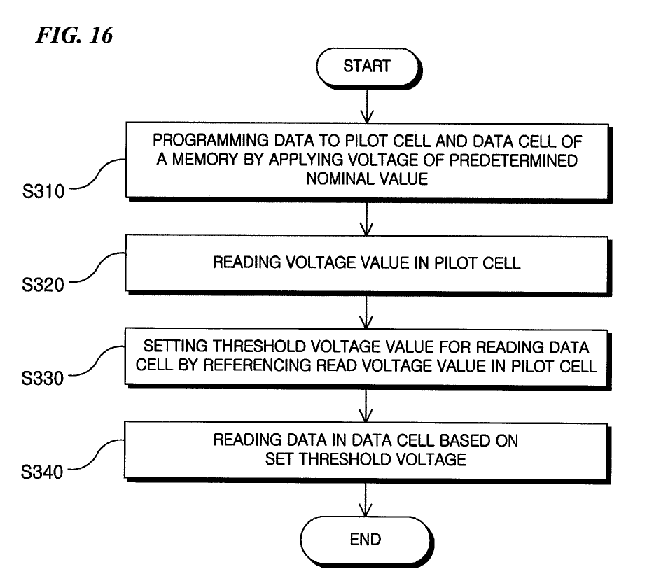

FIG. 16 is a flowchart for a data processing method of a memory according to another aspect of the present invention. It will be apparent to those skilled in the art that additional steps other than steps illustrated in FIG. 16 may be included in the method and some steps may be omitted.

As illustrated in FIG. 16, the memory controller programs data to the pilot cell and the data cell in the memory by using voltage of the predetermined nominal value (S410). As described above, the pilot cell indicates a cell at a predetermined position corresponding to each of at least one nominal value used for programming the memory. According to an aspect of the present invention, the pilot cell may include a plurality of cells corresponding to a plurality of nominal values used for the memory programming, respectively. The pilot cell may be positioned in the same block or the same page as the data cell.

Next, the memory controller reads the written voltage value of the pilot cell (S420). In this case, the memory controller may read the voltage value of the pilot cell with higher resolution than the voltage step among the respective data for programming.

Next, the memory controller sets a threshold voltage value for reading the data cell by referring to the read voltage value of the pilot cell (S430). The threshold voltage value is used as reading voltage of the data cell and according to an aspect, the threshold voltage value may be set to a value lower than the read voltage value of the pilot cell by a predetermined level. Further, according to an aspect of the present invention, the memory controller may obtain the reading voltage values of the plurality of pilot cells programmed by using the same nominal value in the memory and set the threshold voltage value based on an average of the obtained reading voltage values of the plurality of pilot cells.

The memory controller reads the data of the data cell of the memory based on the set threshold voltage value (S440).

Meanwhile, according to an aspect of the present invention, the memory controller may obtain information on the number of erase times of a block or the number of write times of a page at which the pilot cell is positioned. The memory controller may shift the position of the pilot cell based on the information on the number of erase times or the information on the number of write times.

Various aspects or features described herein can be implemented as methods, apparatuses, or manufactured articles using stand programming and/or engineering techniques. Steps and/or operations of a method or algorithm described in association with the aspects disclosed herein can be directly implemented as hardware, a software module executed by a processor, a combination thereof. Additionally, in some aspects, the steps or operations of the method or algorithm can be present as at least one or a predetermined combination of sets of codes or commands on a machine-readable or computer-readable medium and this can be integrated into a computer program article. The manufactured article as the terms used herein is intended to include a computer program accessible by a predetermined appropriate computer-readable device or medium.

The description of the presented exemplary embodiments is provided so that those skilled in the art of the present invention use or implement the present invention. It will be apparent that various modifications of the exemplary embodiments will be apparent to those skilled in the art and general principles defined herein can be applied to other exemplary embodiments without departing from the scope of the present invention. Therefore, the present invention is not limited to the exemplary embodiments presented herein, but should be analyzed within the widest range which is associated with the principles and new features presented herein.

### MODE FOR INVENTION

As previously described, mode for invention is fully described in best mode

### INDUSTRIAL APPLICABILITY

Present invention may be applied to various memories and memory systems which includes the memories.

1. A method for processing data in a memory, the method comprising:
obtaining programming count information of a page on which data is to be programmed;
determining a driving voltage value set including a lowest level value and a highest level value to be programmed on each memory cell in the page based on the obtained programming count information; and
programming the data on each memory cell in the page by using a plurality of voltages between the lowest level value and the highest level value of the determined driving voltage value set,
wherein the lowest level value and the highest level value are shifted according to an increase in the programming count information.

2. The method of claim 1, wherein in the determining, the driving voltage set is determined based on a value of ‘the programming count information (mod ‘the total number of driving voltage level values of the memory cell−1’)’.

3. The method of claim 1, wherein:
the programming count information increases by 1 according to a programming request of data, and
in the determining, a lowest level value and a highest level value of the memory cell to which a first level value and a second level value are allocated, respectively are changed to the second level value and a third level value.

4. The method of claim 1, wherein:
the page includes a pilot cell at a predetermined position, which is set to have a threshold voltage between the lowest level value and the highest level value and a data cell in which the data is programmed, wherein the threshold voltage value programmed to the pilot cell is shifted according to the increase in the programming count information, and
the method further comprises: in response to a read request of the data written in the page,
reading a voltage value written in the pilot cell;
setting a read voltage value for reading the data cell by referring to the read voltage value of the pilot cell; and
reading the data of the data cell based on the set read voltage value.

5. The method of claim 1, wherein:
the memory cell is a multi level cell (MLC) and
the method comprises
determining the size of data of which programming is requested;
programming the data to each memory cell with 1-bit information using the lowest level value and the highest level value when the determined size of the data is smaller than a half of the size of the page;
shifting the lowest level value and the highest level value in response to the overwrite request of the data; and
reprogramming the data to each memory cell of the page by using the shifted lowest level value and highest level value.

6. A memory system comprising:
a memory having a plurality of physical blocks, each of the plurality of physical blocks including a plurality of pages; and
a memory controller configured to control the memory,
wherein the memory controller includes a programming module for writing/erasing data in/from the memory, a reading module for reading the data written in the memory, and a control module controlling the programming module and the reading module,
the control module obtains programming count information of a page on which data is to be programmed and determines a driving voltage value set including a lowest level value and a highest level value to be programmed on each memory cell in the page based on the obtained programming count information,
the programming module programs the data on each memory cell in the page by using a plurality of voltages between the lowest level value and the highest level value of the determined driving voltage value set, and
the lowest level value and the highest level value are shifted according to an increase in the programming count information.
